(19) United States
(12) Patent Application Publication
(10) Pub. No.: US 2010/0283931 A1
(43) Pub. Date: Nov. 11, 2010

(54) TFT ARRAY SUBSTRATE AND LIQUID CRYSTAL DISPLAY DEVICE

(76) Inventors: Satoshi Horiuchi, Osaka (JP); Takaharu Yamada, Osaka (JP); Isao Ogasawara, Osaka (JP)

Correspondence Address: BIRCH STEWART KOLASCH & BIRCH, PO BOX 747, FALLS CHURCH, VA, 22040-0747, US

(21) Appl. No.: 12/811,343

(22) PCT Filed: Dec. 2, 2008
(86) PCT No.: PCT/JP2008/071843

§ 371 Date: Jun. 30, 2010

(30) Foreign Application Priority Data
Apr. 17, 2008 (JP) 2008-107959

(51) Int. Cl. H01L 33/00; H01L 27/06; H01L 27/105; G02F 1/136

(52) U.S. Cl. 349/46; 257/59; 257/71; 257/72; 257/E33.053; 257/E27.016; 257/E27.081

(57) ABSTRACT

In a TFT array substrate (20), connecting points (P10) of a first metal layer (M1) and a second metal layer (M2) are provided in a peripheral region (A20). A driving circuit (B60b), which is at least a part of a driving circuit (60), is provided between the connecting points (P10) and an edge (24) of the TFT array substrate (20).

### TECHNICAL FIELD

The present invention relates to a TFT array substrate including an insulating substrate on which TFT elements are formed, and to a liquid crystal display device in which the TFT array substrate is used.

### BACKGROUND ART

Conventionally, TFT array substrates provided with TFT (Thin Film Transistor) elements are widely used for devices such as display devices for example liquid crystal display devices, and sensor devices.

Each of the TFT elements has electrodes that are connected to connection lines.

Specifically, a gate electrode of each of the TFT elements is connected to a gate bus-line metal, and a source electrode of each of the TFT elements is connected to a source bus-line metal. In a case where, for example, the TFT array substrate is used in a liquid crystal display device, a drain electrode of each of the TFT elements is connected to a pixel electrode.

Particularly in a case where the TFT elements are arranged in a matrix so as to form an array, the gate bus-line metal and the source bus-line metal are formed in such directions that they intersect at right angles with each other on the insulating substrate.

In order not to electrically connect the gate bus-line metal and the source bus-line metal with each other at the intersection points, the gate bus-line metal and the source bus-line metal are respectively formed as different layers on the insulating substrate, so that an insulating layer is sandwiched therebetween. A description of this follows with reference to drawings.

FIG. 6 is a cross sectional view schematically illustrating a configuration of a TFT array substrate. As illustrated in FIG. 6, in a TFT array substrate 20, a gate bus-line metal 40 (first metal, first metal layer M1) is formed on an insulating substrate 30. On the gate bus-line metal 40, a gate insulating film 50 serving as a first insulating layer I1, a source bus-line metal 42 (second metal) serving as a second metal layer M2, and an interlayer insulating film 52 serving as a second insulating film I2 are provided in this order.

These wires (metal wires) of the foregoing metals are variously drawn around.

Here, if the metal wires drawn around is uncovered with the aforementioned respective insulating layers, thereby causing a part of the metal wires be exposed, a corrosion problem arises at the exposed part.

(Patent Literatures 1 and 2)

In view of the above problem, various techniques have been proposed for preventing the metal corrosion.

For example, in order to prevent the corrosion of electrodes and other members, Patent Literature 1 discloses a technique of disposing a seal material so as to prevent liquid crystal from being in contact with connecting electrodes that connect an inspection thin-film transistor and inspection wires.

Moreover, in order to prevent the corrosion, Patent Literature 2 discloses a technique of disposing connecting sections that connect a power supply line and a power supply pad, inside of an outer edge of a sealed region. The connecting sections are connected with each other and a metal is exposed.

### Citation List

Patent Literature 1

Japanese Patent Application Publication, Tokukai, No. 2002-122882 A (Publication Date: Apr. 26, 2002)

Patent Literature 2

Japanese Patent Application Publication, Tokukai, No. 2007-24963 A (Publication Date: Feb. 1, 2007)

Patent Literature 3

Japanese Patent Application Publication, Tokukai, No. 2006-276287 A (Publication Date: Oct. 12, 2006)

### SUMMARY OF INVENTION

However, the foregoing conventional TFT array substrates have a problem that they cannot sufficiently prevent the metal corrosion. A description in this regard follows with reference to drawings.

(Bridge Connection)

In FIG. 7, (a) is a plan view illustrating wires on a TFT array substrate 20.

Described in the following explanation with reference to (a) of FIG. 7 is a case where, for example, a plurality of gate bus-line metals 40a, 40b, and 40c are provided in parallel in an X-direction (refer to an arrow X in (a) of FIG. 7) that is a longitudinal direction of an insulating substrate 30, and a central one of the gate bus-line metals (gate bus-line metal 40b) is skipped when the other two gate bus-line metals (gate bus-line metals 40a and 40c), by which the gate bus-line metal 40b is sandwiched, are electrically connected to each other.

In FIG. 7, (b) is a cross sectional view taken on the line V-V in (a) of FIG. 7. As illustrated in (b) of FIG. 7, the gate bus-line metals 40a, 40b, and 40c are formed as a first metal in a same layer on the insulating substrate 30, i.e., in a first metal layer M1.

On this account, in order to connect the gate bus-line metal 40a and the gate bus-line metal 40c with each other by having the gate bus-line metal 40a and the gate bus-line metal 40c in no contact with the gate bus-line metal 40b, it is necessary to connect the gate bus-line metal 40a and the gate bus-line metal 40c via a layer different from the gate bus-line metal 40b.

Specifically, in a case where the gate bus-line metals 40a and 40c are connected with each other in a Y-direction (refer to an arrow Y in FIG. 7) that orthogonally intersects with an X-direction along which the gate bus-line metals 40a and 40c extend, the gate bus-line metals may be connected in such a manner that a wire is drawn from the first metal layer M1 in which the gate bus-line metal 40 is formed, to the second metal layer M2 in which the source bus-line metal 42 (second metal) is formed (refer to the connection region R10 in (b) of FIG. 7). Note that the second metal layer M2 is a layer provided upper of the first metal layer M1, and the first insulating layer I1 that is a gate insulating film 50 is sandwiched between the first metal layer M1 and the second metal layer M2. This wire thus drawn out allows the gate bus-line metal 40a and the gate bus-line metal 40c to be connected to each other at the second metal layer M2.

In other words, it is conceived that the two gate bus-line metals 40 are connected to each other via a bridge of the second metal layer M2.

In the foregoing configuration, it is necessary to connect the first metal layer M1 and the second metal layer M2 as shown in the connection region R10. Examples of a method of how to connect the first metal layer M1 and the second metal layer M2 include a connecting method using a via hole (via hole connection) and a connection method using a third metal (via a third metal layer) (third metal connection).

(Via Hole Connection)

First, the connection method using a via hole is described with reference to FIG. 8. FIG. 8 is a cross sectional view schematically illustrating a configuration of the TFT array substrate 20.

As illustrated in FIG. 8, in the via hole connection, a via hole 46 that penetrates through the gate insulating film 50 is opened at a part where the gate bus-line metal 40 and the source bus-line metal 42 overlap each other. The gate bus-line metal 40 and the source-bus line metal 42 are electrically connected with each other via the via hole 46.

In other words, the first metal layer M1 and the second metal layer M2 are connected with each other via the via hole 46 penetrating through the first insulating layer I1.

(Third Metal Connection)

Next described is the third metal connection with reference to (a) and (b) of FIG. 9. Both (a) and (b) of FIG. 9 are cross sectional views each schematically illustrating a configuration of the TFT array substrate 20 in forming the third metal connection. In FIG. 9, (a) illustrates a configuration of the TFT array substrate 20 subsequent to the configuration shown in FIG. 6. In FIG. 9, (b) illustrates a configuration of the TFT array substrate 20 subsequent to the configuration shown in (a) of FIG. 9.

As illustrated in (a) of FIG. 9, in order to form the third metal connection, first, the interlayer insulating film 52 serving as the second insulating layer 12 is removed from the connection region R10 of the TFT array substrate 20 illustrated in FIG. 6. This exposes the source bus-line metal 42 serving as the second metal layer M2.

Then, the gate insulating film 50 serving as the first insulating layer I1 is removed to expose the gate bus-line metal 40.

Here, to achieve a reliable connection by a third metal layer described later, it is preferable that an edge surface of the source bus-line metal 42 and an edge surface of the gate insulating film 50 are in line with each other.

Then, as illustrated in (b) of FIG. 9, a pixel electrode metal 44 (third metal) is formed as the third metal layer M3 in the connection region R10 of the TFT array substrate 20.

As a result, the gate bus-line metal 40 serving as the first metal layer M1 and the source bus-line metal 42 serving as the second metal layer M2 are electrically connected to each other via the pixel electrode metal 44 serving as the third metal layer M3.

The third metal connection is advantageous in terms of manufacturing, since the number of processing steps required is reduced as compared to the via hole connection method. Specifically, the third metal connection method can omit, for example, a via hole opening step for opening the via hole 46.

Moreover, the third metal connection can be easily carried out by successively patterning (i) the interlayer insulating film 52 as the second insulating layer I2, (ii) the source bus-line metal 42 as the second metal layer M2, and (iii) the interlayer insulating film 52 as the first interlayer insulating layer 11.

(Corrosion)

However, the configuration of the third metal connection has a problem that metal corrosion easily occurs in the connection region R10. That is, as illustrated in (b) of FIG. 9, in the connection region R10, the third metal layer M3 for connecting the first metal layer M1 and the second metal layer M2 is exposed.

Further, the pixel electrode metal 44 is generally a thin film metal layer such as an ITO (Indium Tin Oxide) thin film, in a case where the third metal layer M3 is formed with the pixel electrode metal 44 as described above. Hence, it is likely that the source bus-line metal 42 as the second metal layer M2 corrodes even if the source bus-line metal 42 is covered with the pixel electrode metal 44.

(Position of Seal)

In view of the above, position to dispose a seal is considered in terms of preventing corrosion of the metal in the connection region R10. This is described in the following with reference to FIG. 10. FIG. 10 is a plan view schematically illustrating a configuration of a peripheral part of the TFT array substrate 20.

As illustrated in FIG. 10, in a planar view, a central part of the TFT array substrate 20 serves as a display region A10. A peripheral region A20 is provided so as to surround the display region A10. The peripheral region A20 is in the proximity of the edges 24 of the TFT array substrate 20, and is provided with driving circuits 60 etc.

In a case where, for example, gate driving circuits 62 are provided as the driving circuits 60 on the right and the left of the display region A10, respectively, the gate driving circuits 62 are connected to the wires and the like in the display region A10 via gate-bus lines 41 and the like.

Moreover, in a case where, for example, a driver 100 is provided on a top or a bottom of the display region A10, the driver 100 is connected to the gate driving circuits 62 via gate driving circuit signal wires 110 such as clock wires and the like, or via the wires of the display region A10, source bus lines 43, and the like.

The TFT array substrate 20 and a counter substrate (not illustrated) are bonded together by a seal 90. The seal 90 is provided on an inner side and along the edges 24 of the TFT substrate 20 so as to form a shape of a frame.

A specific description follows with reference to FIG. 11 illustrating the peripheral region A20 of the TFT array substrate 20.

As illustrated in FIG. 11, in the peripheral region A20 of the TFT array substrate 20, driving circuits 60 are formed so as to face the display region A10.

Between the driving circuits 60 and the edge 24 of the TFT array substrate 20, wires such as a low-potential power supply line (Vss) 70 and clock wiring (CK) 72 are formed. In some cases, these wires and the driving circuits 60 are connected in a lateral direction of the TFT array substrate 20, i.e., in a direction of an arrow X.

Particularly, in a case where the clock wiring 72 is formed by including a plurality of wires arranged parallel to each other as like clock wires 72a and 72b, and there is a need to make a connection by bridging over an adjacent wire, the third metal connection is formed first, as described with reference to (b) of FIG. 9.

A specific example is a case where the low-potential power supply line 70 and the driving circuits 60 are to be connected without having the low-potential power supply line 70 and the driving circuits 60 touching the clock wires 72 formed therebetween. In such a case, the third metal connections are formed on the low-potential power supply line 70 (see connecting points P10 in FIG. 11). In this way, the second metal layer M2 bridges over the adjacent clock wires 72a and 72b that are formed in the same first metal layer M1 as the low-potential power supply line 70. Consequently, the low-potential power supply line 70 and the driving circuits 60 are connected without having them touching the clock wires 72a and 72b.

Also in the case where the clock wires 72 are to be connected with the driving circuits 60, the third metal connections are formed as necessary in a similar manner.

As already described with reference to (b) of FIG. 9, in the third metal connection, it is likely that the third metal, which connects the first metal layer M1 and the second metal layer M2, is exposed.

Furthermore, in a case where the third metal layer M3 is made of the pixel electrode metal 44 as the aforementioned, it is likely that the source bus-line metal 42 as the second metal layer M2 easily corrode even if it is covered with the pixel electrode metal 44. This is because the pixel electrode metal 44 is generally a thin film metal layer such as an ITO (Indium Tin Oxide) thin film.

On this account, in order to prevent corrosion and the like of the foregoing metal layers, the TFT array substrate 20 is configured in such a manner that the seal 90 covers the connecting points P10 at which the third metal connections are formed.

In this configuration, the aforementioned connection region R10 in which the third metal connections are formed is covered with the seal 90. Therefore, it is possible to prevent the third metal layer M3 from directly touching air.

As a result, it becomes possible to prevent corrosion of the metal layers.

However, as illustrated in FIG. 11, the connecting points P10 where the third metal connections are formed are conventionally formed in the proximity of the edge 24 of the TFT array substrate 20. That is, various wires such as the low-potential power supply line 70 and the clock wires 72 in the peripheral region A20 are formed on an outer side than the various driving circuits 60. In other words, these wires are formed between the various driving circuits 60 and the edge 24 of the TFT array substrate 20.

That is to say, the display region A10 is disposed in the central part of the TFT array substrate 20, and from the display region A10 toward the edge 24 of the TFT array substrate 20, the driving circuits 60 and the various wires such as the low-potential power supply line 70, the clock wires 72, and so on are successively disposed in this order.

(Position of Seal)

In order to determine the position of the seal 90, it is necessary to take the following factors into consideration, for example.

Firstly, for sufficiently carrying out the function of bonding the TFT array substrate and the counter substrate together, the seal 90 is required to have a predetermined width (D1 shown in FIG. 11, i.e., a distance from a seal inner edge 92 to a seal outer edge 94 of the seal 90).

Secondly, in terms of securing a margin for dealing with displacement that may occur at the time of forming the seal 90 on the substrate, it is necessary to secure a predetermined width (D2 shown in FIG. 11, fringe seal width) between the outer edge 94 of the seal 90 and the position of the connecting point P10 which is closest to the edge 24 of the TFT array substrate 20 among a group of the connecting points P10 (first seal reference position, K1 in FIG. 11).

Furthermore, in order to further prevent the corrosion of the metal layers, it is conceived that all the connecting points P10 where third metal connections are formed are covered with the seal 90. On this account, in determining the position of the seal 90, a configuration is conceivable in which the position of the seal 90 is determined so that a connection point P10 (second seal reference position, K2 in FIG. 11) that is farthest from the edge 24 of the TFT array substrate 20 among the group of connection points P10 is covered by the seal 90. This configuration leads to that the seal 90 covers all of the group of the connecting points P10 where the third metal connections are respectively formed.

FIG. 11 shows the position of the seal 90 that is determined in consideration of the above factors. That is, the seal 90 is disposed to be positioned to have a width so that the second seal reference position is included, while a certain seal width D1 is secured from the first seal reference position K1.

In a case where the seal 90 is thus formed, the width of the frame in the TFT array substrate 20 of the display device becomes D3 as shown in FIG. 11.

Here, the “frame” means a region on the periphery of the display device where the seal 90 and the driving circuits 60 are disposed and thus no display is performed.

The conventional configuration has a problem that the width D3 of the frame is wide as illustrated in, for example, FIG. 11. That is, according to the conventional arrangement illustrated in FIG. 11, the frame has a width that is close to a sum of the width of the driving circuits 60 and the seal width D1. Also the seal width D1 is wide, because it not only includes the first seal reference positions K1 and, depending on configurations, the second seal reference positions K2, but it also includes the fringe seal width D2 from the first seal reference position K1 to the outer edge 94 of the seal.

(Patent Literature 3)

The Patent Literature 3 discloses, for the purpose of narrowing a frame of a display device, a technique in which a part of a driving circuit is covered with a seal material. However, while the technique disclosed in Patent Literature 3 can reduce the width from the outer edge of the seal to the edge of the substrate, it cannot sufficiently reduce a region other than the display region, i.e., a frame where no display is performed due to formation of the seal, the driving circuit, and the others therein.

The present invention is achieved in view of the above problem, and an object of the present invention is to provide a TFT array substrate with a narrow frame. Another object of the present invention is to provide a TFT array substrate with a narrow frame in which corrosion of metal is prevented.

In order to attain the foregoing objects, a TFT array substrate according to the present invention includes: an insulating substrate on which TFT elements are arranged in a matrix manner; a first metal and a second metal for providing on the insulating substrate gate bus-lines and source bus-lines, respectively, which gate bus-lines and source bus-lines are connected to the TFT elements; an insulating layer provided between the first metal and the second metal so that the first metal and the second metal are provided as different layers on the insulating substrate; at least one connecting point provided in a peripheral region around a TFT element region of the insulating substrate, for electrically connecting the first metal and the second metal together, the TFT element region being a region in which the TFT elements are arranged in the matrix manner; a third metal that differs from the first metal and the second metal, via which the first metal and the second metal are electrically connected at the at least one connecting point; and a driving circuit provided in the peripheral region for driving the TFT elements, and in the TFT array substrate according to the present invention, at least a part of the third metal being exposed at the at least one connecting point, and at least a part of the driving circuit being provided in the peripheral region, between the at least one connecting point and an edge of the insulating substrate.

According to the above configuration, in a peripheral region of the TFT array substrate, driving circuits are formed on an outer side than points (connecting points) where different metal layers on the insulating substrate are connected with each other.

Generally, in a case where a TFT array substrate is bonded to another counter substrate by a seal or the like, the seal or the like having a preferred width is formed on an outer side than at least the connecting points, in view of displacement or the like.

Furthermore, according to the above configuration, a driving circuit is provided on an outer side than the connecting points. Hence, it is possible to prevent the frame from becoming wider due to providing the seal or the like.

Therefore, with the above configuration, it is possible to provide a TFT array substrate having a narrow frame.

In the TFT array substrate according to the present invention, the exposed third metal may be in no contact with air by use of an insulating material.

With the above configuration, the exposed third metal is not exposed to air. As such, it is possible to prevent metal corrosion.

That is, as described above, the exposed metal, and in a case where particularly the film thickness of the exposed metal is thin, also its underlying metal may corrode caused by the metal being in contact with air.

Regarding this point, according to the above configuration, the exposed metal is in no contact with air by use of the insulating material. Hence, metal corrosion is not likely to occur.

Furthermore, in the TFT array substrate according to the present invention, a plurality of the at least one connecting point may be provided in the peripheral region, and the exposed third metal in at least a part of the plurality of the at least one connecting point is in no contact with air by the third metal being covered with an insulating material.

Moreover, in the TFT array substrate according to the present invention, the exposed third metal in all of the at least one connecting point may be in no contact with air by the third metal being covered with an insulating material.

According to the above configuration, at least a part, preferably all of the exposed third metal is covered with the insulating material, so that the third metal is partially or entirely in no contact with air. Hence, it is possible to more reliably prevent corrosion of the metal.

Furthermore, in the TFT array substrate according to the present invention, an insulating material may be provided in the peripheral region, and the insulating material may be provided closer to edge of the insulating substrate than the exposed third metal in all of the at least one connecting point, so that the exposed third metal is in no contact with air.

Moreover, in the TFT array substrate according to the present invention, the exposed third metal in all of the at least one connecting point may be surrounded by the insulating material provided along the edge of the insulating substrate.

According to the above configuration, the insulating material is in no contact with the exposed third metal and the connecting points.

This makes it possible to prevent any changes in the insulating material such as a reduction in thickness of the insulating material, caused by the insulating material entering into contact holes opened at the connecting points.

In addition, in a case where the insulating substrate is used as for example a liquid crystal display device, the distance (gap) between the insulating substrate and the counter substrate can be easily maintained. As a result, it is possible to prevent the thickness of the liquid crystal layer sandwiched between the two substrates from changing.

Moreover, in a case where a conductive material is mixed in the insulating material (for example, a seal material in which a conductive material is mixed), this material is not in contact with the exposed third metal. This makes it possible to prevent electrical leakage (for example, a conduction to counter electrodes on the counter substrate).

Moreover, in the TFT array substrate according to the present invention, an insulating material may be provided in the peripheral region, and the insulating material may cover the driving circuit provided between the at least one connecting point and an edge of the insulating substrate in the peripheral region.

According to the above configuration, the seal is provided so as to cover the driving circuit disposed in the peripheral region. As such, it is possible to further prevent the frame from enlarging caused by providing the seal.

Moreover, in the TFT array substrate according to the present invention, at least one of a three-terminal element, a resistance element, and a capacitor element may be provided in the driving circuit provided between the at least one connecting point and an edge of the insulating substrate in the peripheral region.

Furthermore, in the TFT array substrate according to the present invention, a three-terminal element, a resistance element, and a capacitor element may be provided in the driving circuit provided between the at least one connecting point and an edge of the insulating substrate in the peripheral region.

Furthermore, in the TFT array substrate according to the present invention, at least one signal line may be formed in the peripheral region, the signal line may extend in a same direction as an edge of the insulating substrate in the peripheral region, and at least a part of the driving circuit may be provided between the at least one signal line and the edge of the insulating substrate.

According to the above configuration, elements such as a three-terminal element, a resistance element, a capacitor element, and the like that are essential for configuring the circuits are provided in the driving circuit and the like.

In particular, in a case where a signal line is arranged between the driving circuit and the TFT element region, it is necessary to connect the driving circuit with the signal lines.

In forming such connections, the connecting points tend to be formed over a wide range. However, with the present invention, it is possible to hold down the enlargement of the frame, because the driving circuits are formed on an outer side than the connecting points.

In the TFT array substrate according to the present invention, the at least one signal line may include (i) a clock wire and (ii) a direct current power supply line for supplying a potential that causes the TFT elements to be turned off, and the direct current power supply line may be formed in the peripheral region between the driving circuit and the edge of the insulating substrate.

Generally, it is preferable that a stable potential is supplied to the direct current power supply line such as the low-potential power supply line which supplies a potential that causes the TFT elements to be turned off. With the above configuration, the direct current power supply line is formed on an outer side than the driving circuit. This makes it easy to supply a stable potential.

Furthermore, in the TFT array substrate according to the present invention, a wire formed by use of the first metal and a wire formed by use of the second metal may be formed in the peripheral region in such a manner that the wire formed by use of the first metal and the wire formed by use of the second metal sandwich the insulating layer and intersect with each other in a planar view, and a substantial width of at least one of the wire formed by use of the first metal and the wire formed by use of the second metal may be narrowed in a region in which the wire formed by use of the first metal and the wire formed by use of the second metal intersect with each other.

Furthermore, in the TFT array substrate according to the present invention, a wire formed by use of the first metal and a wire formed by use of the second metal may be provided in the peripheral region in such a manner that the wire formed by use of the first metal and the wire formed by use of the second metal sandwich the insulating layer and intersect with each other in a planar view, and a part of at least one of the wire formed by use of the first metal and the wire formed by use of the second metal may be hollowed in the region where the wire formed by use of the first metal and the wire formed by use of the second metal intersect with each other.

According to the above configuration, in a case where the wires formed by use of the first metal and the wires formed by use of the second metal intersect with each other, it is possible to reduce an area in the intersecting region in which the wires overlap each other.

The substantial width of the wire is not an apparent maximal width of the wire, but it is an effective width in a direction that orthogonally intersects with a direction along which the wire extends (width of the region in which the metal is formed).

Therefore, in a case where, for example, the wire is hollowed, the substantial width means the width of the metal excluding the part that is hollowed.

Furthermore, in the TFT array substrate according to the present invention, the insulating substrate may be bonded to a counter substrate by use of a seal, and the insulating material that covers the third metal may serve as the seal.

According to the above configuration, the insulating material that covers the third metal is a seal for bonding to the counter substrate. Hence, it is possible to prevent metal from corroding, without particularly adding a step.

In the TFT array substrate according to the present invention, pixel electrodes connected to the TFT elements may be provided in the TFT element region, and the pixel electrodes may be formed by use of the third metal.

According to the above configuration, the third metal is a metal that is used for forming the pixel electrode. Hence, it is possible to connect the first metal with the second metal without particularly adding a step.

In the TFT array substrate according to the present invention, the driving circuit provided in the peripheral region between the at least one connecting point and an edge of the insulating substrate may include a three-terminal element, and the three-terminal element may be an element outputting a signal to the TFT elements.

In the TFT array substrate according to the present invention, the three-terminal element may make up a pull-up circuit outputting to the TFT elements a signal that causes the TFT elements to be turned on.

Furthermore, in the TFT array substrate according to the present invention, the three-terminal element may make up a pull-down circuit for outputting to the TFT element a signal that causes the TFT elements to be turned off.

Moreover, in the TFT array substrate according to the present invention, the driving circuit provided in the peripheral region between the at least one connecting point and an edge of the insulating substrate may include a bootstrap capacitor element.

According to the above configuration, the driving circuit has elements that output signals to the TFT elements, in particular, pull-up circuits and pull-down circuits, or a relatively large-sized circuit such as a bootstrap capacitor element.

Therefore, it is possible to prevent the enlargement of the frame more effectively.

A liquid crystal display device according to the present invention may include the foregoing TFT array substrate.

With the above configuration, it is possible to narrow the frame of a liquid crystal display device.

As described above, in the TFT array substrate 20 of the present invention, at least a part of a driving circuit is provided in a peripheral region, between connecting points and an edge of the insulating substrate.

Therefore, the present invention achieves an effect of providing a TFT array substrate with a narrow frame.

### BRIEF DESCRIPTION OF DRAWINGS

FIG. 1 illustrates an embodiment of the present invention schematically showing a configuration of a TFT array substrate.

FIG. 2 is a cross sectional view taken on line A-A of FIG. 1.

FIG. 3 is a cross sectional view taken on line B-B of FIG. 1.

FIG. 4 is a view schematically illustrating a configuration of a driving circuit of the present invention.

FIG. 5 illustrates another embodiment of the present invention schematically showing a configuration of a TFT array substrate.

FIG. 6 is a cross sectional view schematically illustrating a configuration of the TFT array substrate.

FIG. 7 illustrates wires on the TFT array substrate: (a) is a plan view and (b) is a cross sectional view taken on line V-V in (a).

FIG. 8 is a cross sectional view schematically illustrating a configuration of the TFT array substrate.

FIG. 9 is a cross sectional view schematically illustrating a configuration of the TFT array substrate: (a) illustrates a configuration subsequent to FIG. 6, and (b) illustrates a configuration subsequent to (a) of FIG. 9.

FIG. 10 is a plan view schematically illustrating a configuration of the TFT array substrate.

FIG. 11 is a view schematically illustrating a configuration of the peripheral region of the TFT array substrate.

### REFERENCE SIGNS LIST

10 Liquid Crystal Display Device
20 TFT array Substrate
22 Counter Substrate
24 Edge
30 Insulating Substrate
44 Pixel Electrode Metal (Metal that forms a pixel electrode)
M1 First Metal Layer (First Metal)
M2 Second Metal Layer (Second Metal)
M3 Third Metal Layer (Third Metal)
50 Gate Insulating Film (Insulating Layer)
60 Driving Circuit
70 Low-Potential Power Supply Line
72 Clock Wire
90 Seal (Insulating Material)
134 Pull-Up Means (Pull-Up Circuit)
136 Pull-Down Means (Pull-Down Circuit)
P10 Connecting Point
A10 Display Region (TFT Element Region)
A20 Peripheral Region

### DESCRIPTION OF EMBODIMENTS

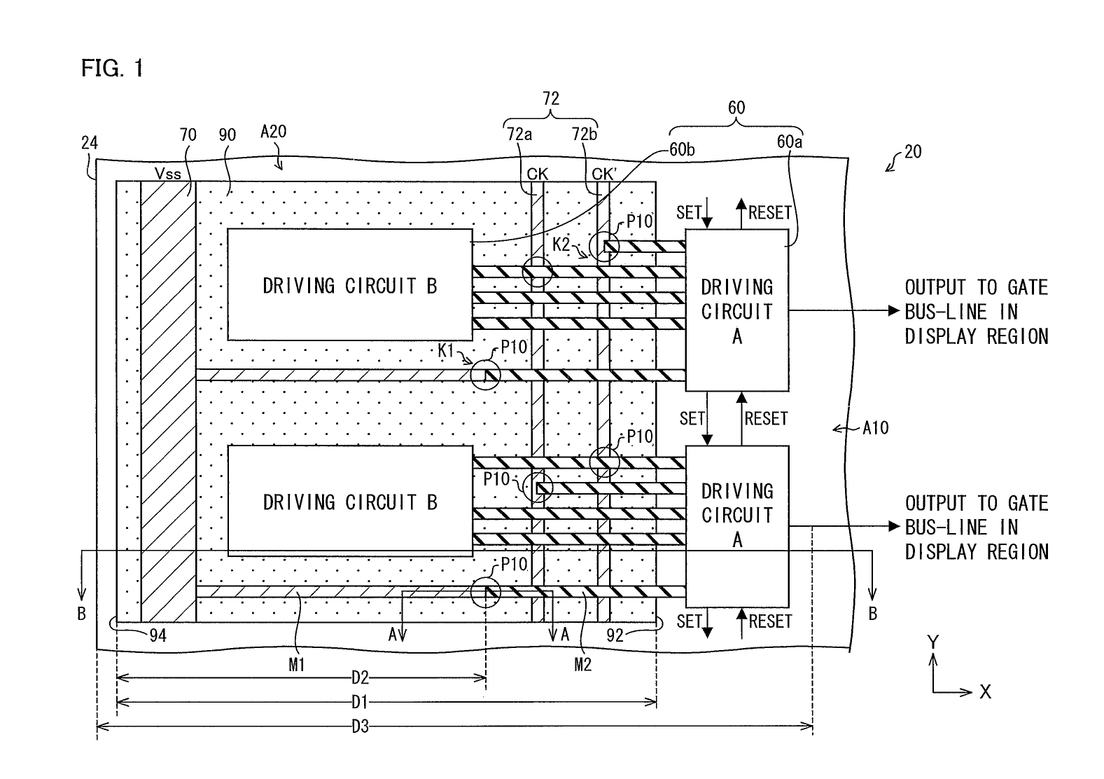

The following describes an embodiment of the present invention with reference to FIG. 1 and the like. FIG. 1 is a view schematically illustrating a configuration of a TFT array substrate according to the embodiment.

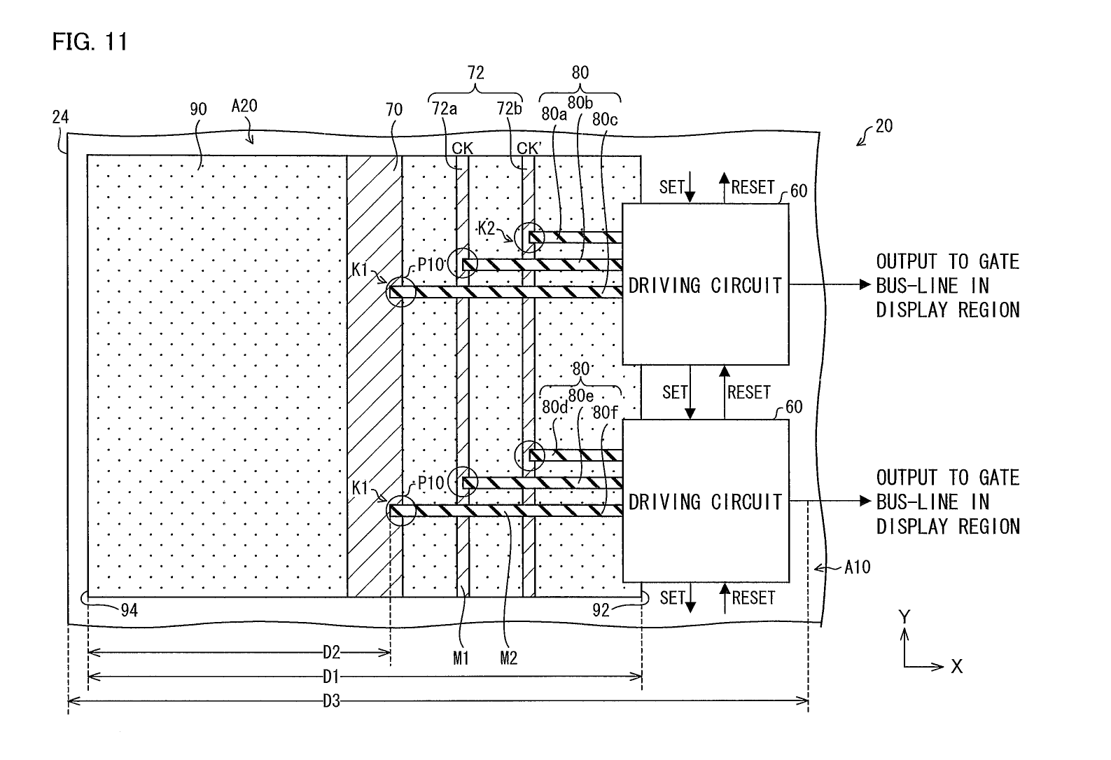

Unlike the TFT array substrate 20 described with reference to FIG. 11, a TFT array substrate 20 according to the present embodiment, as illustrated in FIG. 1, has a driving circuit 60 that is divided into a driving circuit A 60a and a driving circuit B 60b.

In the TFT array substrate 20 illustrated in FIG. 11, the low-potential power supply line 70 and the clock wires 72a and 72b are arranged adjacent to each other, each of which extends along a Y-direction; on the other hand, the TFT array substrate 20 of the present embodiment has the low-potential power supply line 70 and the clock wires 72a and 72b arranged apart from each other. The low-potential power supply line 70 is a direct current power supply line supplying a potential that causes the TFT electrodes to be turned off.

The driving circuit B 60b, which is one of the two driving circuits into which the driving circuit 60 is divided, is provided between the low-potential power supply line 70 and the clock wires 72a and 72b.

In other words, the configuration illustrated in FIG. 11 is configured as follows: on the TFT array substrate 20 in which the TFT electrodes are arranged on an insulating substrate in a matrix manner, the display region A10 provided as a TFT element region in the central part of the TFT array substrate 20 is disposed, and thereafter, the driving circuits 60 and the various wires such as the low-potential power supply line 70 and the clock wires 72, are arranged in this order, toward the edge 24 of the TFT array substrate 20.

In contrast, the TFT array substrate 20 of the present embodiment has the display region A10 disposed in the central part of the TFT array substrate 20, then, toward the edge 24 of the TFT array substrate 20, the driving circuit A 60a, a part of the various wires that extend in the Y-direction or more specifically the clock wires 72a and 72b, and the other driving circuit B 60b of the divided driving circuit 60 are disposed in this order. Finally, the low-potential power supply line 70 is provided between the driving circuit B 60b and the TFT array substrate 20.

In such a configuration, the wires that extend in an X-direction for connecting (i) the wires that extend in the Y-direction to (ii) the driving circuit 60a mainly intersect with the wires that extend in a Y-direction at a position between the driving circuit A 60a and the driving circuit B 60b.

In other words, it is therefore necessary to have the wires that extend in the X-direction intersect with and bridge over the wires that extend in the Y-direction, between the driving circuit A 60a and the driving circuit B 60b.

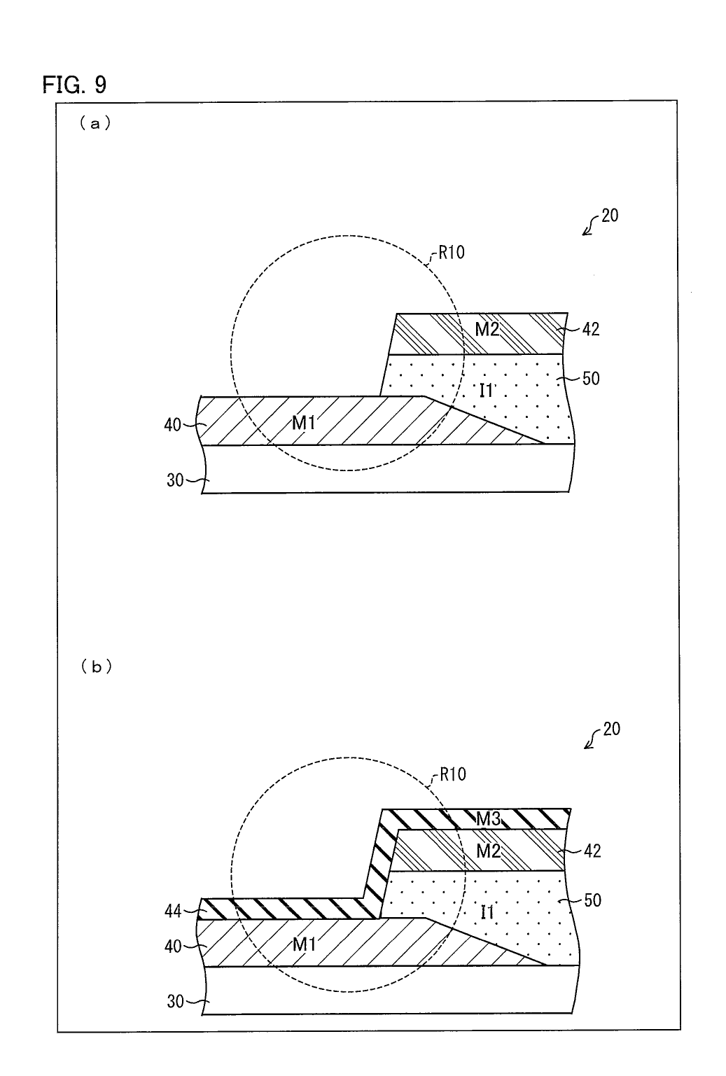

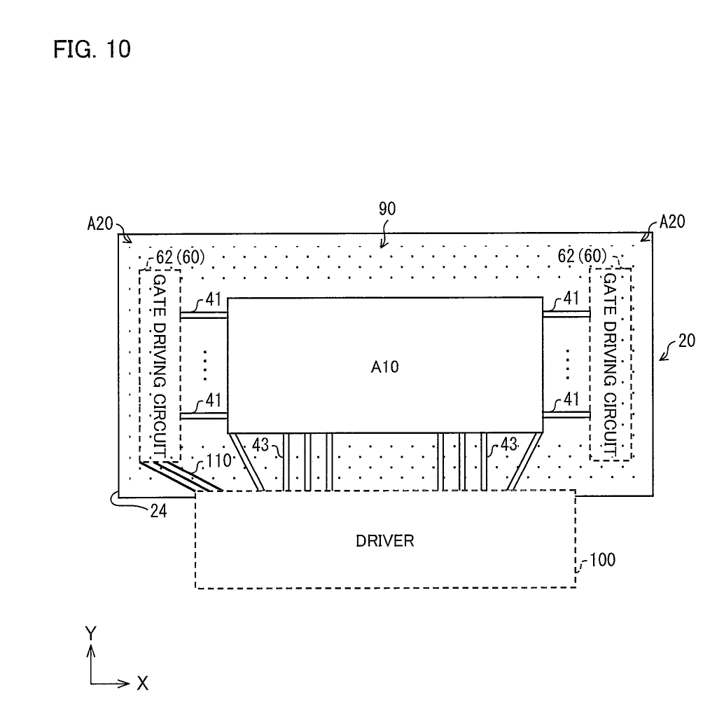

On this account, in most cases, the configuration of the third metal connections as already described with reference to (b) of FIG. 9 are mainly formed between the driving circuit A 60a and the driving circuit B 60b. Specifically, the third metal connections are formed at the connecting points P10 shown in FIG. 1.

In order to prevent the corrosion of the metal, the connecting points P10 where the third metal connections are respectively formed may be covered with the seal 90 so that the metal is in no contact with air.

The following describes where to provide the seal 90 and a width of the seal 90, in the present embodiment.

(Position of Seal)

As already described with reference to FIG. 11, in order to determine the position of the seal 90, it is necessary to consider, for example, the following factors.

The seal 90 is required to have a certain width so as to sufficiently carry out the function of bonding the TFT array substrate and the counter substrate.

In addition, it is necessary to cover the wires and the connecting points P10 on which the third metal connections are formed, upon securing a margin for dealing with any displacement that occurs when providing the seal 90 on the substrate.

In this regard, it is possible in the TFT array substrate 20 of the present embodiment to dispose the seal 90 in such a manner that the seal 90 and the driving circuit 60 are increased in parts that overlap each other. That is, in the present embodiment, one of the divided driving circuits 60, i.e., the driving circuit B 60b, is formed between the outer edge 94 of the seal 90 and the connecting point that is closest to the display region A10 among the connecting points P10. In other words, the driving circuit B 60b is formed between the outer edge 94 of the seal 90 and the second seal reference position K2 which is a point far from the edge 24 of the TFT array substrate 20.

Therefore, in a planar view, the seal 90 overlaps not only the connecting points P10 and the wires such as the low-potential power supply line 70, but also the driving circuit B 60b.

As a result, in the TFT array substrate 20 of the present embodiment, it is possible to shorten the distance between the display region A10 and the outer edge 94 of the seal.

This makes it possible to narrow the frame of the TFT substrate 20.

As already described, the “frame” means a region on the periphery of the display device where the seal 90 and the driving circuits 60 are disposed and thus no display is performed.

According to the TFT array substrate 20 thus configured, size of the driving circuits 60 formed in the region other than the seal 90 is reduced without widening the seal width D1 but maintaining or rather narrowing the seal width D1.

This allows shortening the distance from the display region A10 to the inner edge 92 of the seal, thereby resulting in shortening the distance from the display region A10 to the outer edge 94 of the seal 90.

As described above, in the TFT array substrate 20 according to the present embodiment, it is possible to narrow the frame by dividing the driving circuit 60 into a plurality of driving circuits and covering a part thereof with the seal 90. In addition, it is possible to prevent the corrosion of metal by covering the connecting points 10 with the seal 90, where the third metal connections are formed.

(Cross Section Configuration)

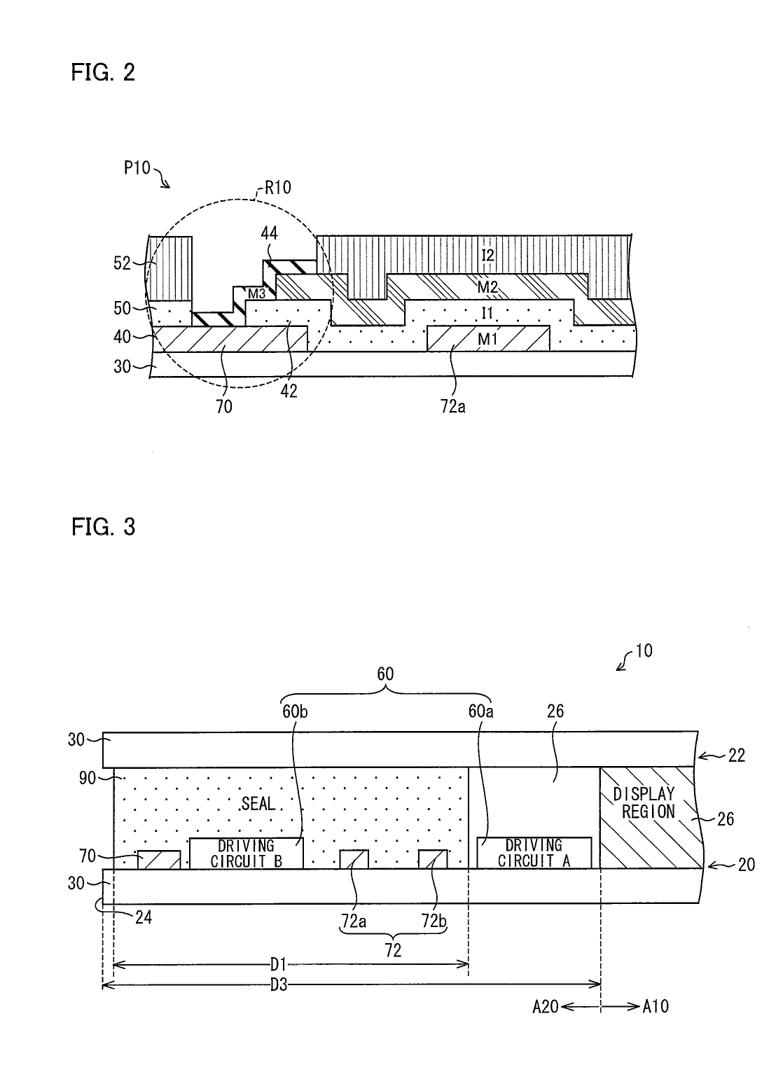

Next described is a cross section of the TFT array substrate 20 of the present embodiment, with reference to FIG. 2. FIG. 2 is a cross sectional view of the TFT array substrate 20 taken on the line A-A of FIG. 1.

As illustrated in FIG. 2, the low-potential power supply line 70 is formed in the first metal layer M1, and the clock wiring line 72a is formed in the same first metal layer M1. As such, in order to connect the low-potential power supply line 70 with, for example, the driving circuit A 60a without being electrically connected to the clock wiring 72a, it is necessary to take a detour via a layer other than the first metal layer M1, such as the second metal layer M2.

On this account, as illustrated in FIG. 2, the configuration of the aforementioned third metal connection is formed in the connecting point P10. In other words, the configuration is formed in which the first metal layer M1 and the second metal layer M2 are connected with each other by the third metal such as a pixel electrode metal.

In the third metal connection, instead of the metal being exposed, the present embodiment has the metal covered with the seal 90, as the aforementioned. Therefore, corrosion is not likely to occur.

The wire in the first metal layer M1 is bridged over via the second metal layer M2, as illustrated in FIG. 2. Then, a similar configuration of the third metal connection allows connection of the second metal layer M2 with the first metal layer M1 again.

Next is described a cross section configuration of the TFT array substrate of the present embodiment in a case where the TFT array substrate is used in a liquid crystal display device 10. Reference is made to FIG. 3.

FIG. 3 is a cross sectional view of the TFT array substrate of the present embodiment taken on line B-B of FIG. 1 in a case where the TFT array substrate is used in a liquid crystal display device.

As illustrated in FIG. 3, the liquid crystal display device 10 is configured such that a liquid crystal layer 26 is sandwiched between two opposing insulating substrates 30.

Specifically, the liquid crystal layer 26 is sandwiched between the counter substrate 22 and the TFT array substrate 20 on which the driving circuits 60 are formed.

In addition, the seal 90 is provided for the purpose of fixing the TFT array substrate 20 and the counter substrate 22 at a bonded state and maintaining a so-called gap, i.e., a distance between the TFT array substrate 20 and the counter substrate 22, at a predetermined value.

In the liquid crystal display device 10 according to the present embodiment, the driving circuit 60 is divided into a driving circuit A 60a and a driving circuit B 60b. Between the driving circuit A 60a and the driving circuit B 60b, clock wires 72a and 72b are formed as a kind of signal lines.

Moreover, between the driving circuit B 60b and the edge 24 of the TFT array substrate 20, a low-potential power supply line 70 is provided as a kind of a signal line.

It is required that a stable voltage is supplied to the low-potential power supply line. In the present embodiment, the low-potential power supply line 70 is provided on an outer side than the driving circuit 60. This makes it possible to supply a stable voltage.

In the configuration illustrated in FIG. 3, the clock wires 72a and 72b are covered with the seal 90. Therefore, the connecting points P10 (see for example FIG. 1) formed on the clock wires 72a and 72b are covered with the seal 90.

In the present embodiment, the seal 90 is made of an insulating material. Hence, the configuration of the third metal connections formed in the connecting points P10 are covered with the insulating material.

Hence, in the connection region R10, an exposed part of the metal in the third metal connection is covered with the insulating material and is not likely to directly be in contact with air. This makes it possible to prevent the corrosion of the metal in the third metal connection.

(Seal Material in Which Conductive Material is Mixed)

The liquid crystal display device 10 illustrated in FIG. 3 is configured such that the clock wires 72 formed between the driving circuit A 60a and the driving circuit B 60b are covered with the seal 90. However, the configuration of the liquid crystal display device 10 is not limited thereto. It is also possible to cover, for example, just a part of the clock wires 72.

Alternatively, it is also possible to configure the liquid crystal display device so that just the low-potential power supply line 70 and the driving circuit B 60b are covered with the seal 90, and the clock wires 72 are not covered with the seal 90.

Such a configuration is especially advantageous in a case where, for example, a seal material that mixes a conductive material into the seal 90 is used. That is, as already described, there are cases where the third metal connections having exposed parts of the metal are formed on the clock wires 72.

In such cases, the clock wires 72 may be covered with the seal material that mixes a conductive material into the seal 90. This may lead to a defect that the exposed third metal in the third metal connections and the counter electrode formed on the counter substrate 22 become electrically connected via the conductive seal 90.

It is possible to avoid this defect by limiting the area to be covered with the seal 90 to the driving circuit B 60b, and not covering the clock wires 72 with the seal 90.

One exemplar arrangement of the above-described seal 90 is a case where the seal 90 as an insulating material is disposed closer to the edge 24 of the insulating substrate 30 than the third metal that is exposed in the connecting points.

More specifically, the seal 90 can be provided along the edge 24 of the insulating substrate 30 so as to surround the exposed third metal within the inner side of the seal 90.

As shown in the above-described configurations, it is possible to dispose the seal 90 of the present invention so as to cover all, a part, or none of the exposed third metal.

(Driving Circuit)

Next is described an overview of the driving circuit 60 in the TFT array substrate 20 of the present embodiment, by way of example.

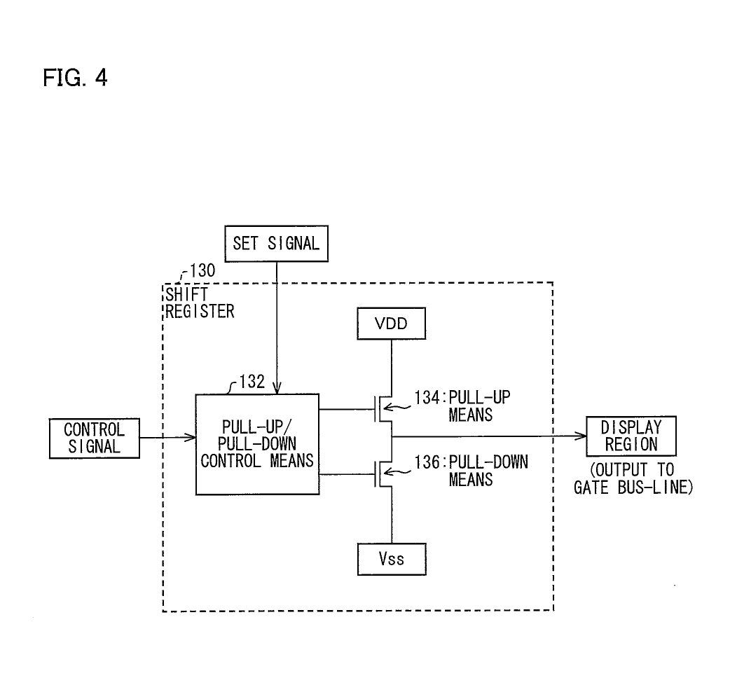

FIG. 4 is a view schematically illustrating a configuration of the driving circuit in the present embodiment.

The driving circuit of the present embodiment is mainly made up of pull-up/pull-down control means 132, pull-up means 134, and pull-down means 136, and operates as a shift register.

Here, each of the pull-up means 134 and the pull-down means 136 represents a circuit (a pull-up circuit, a pull-down circuit) configured by a three-terminal element or the like.

Control signals such as a clock signal (CK), and set signals transmitted from any of the preceding stages are inputted into the pull-up/pull-down control means 132. Depending on configurations, the pull-up/pull-down control means 132 outputs a reset signal to any of the preceding stages.

The pull-up/pull-down control means 132 controls the pull-up means 134 and the pull-down means 136 that are connected to the pull-up/pull-down control means 132.

More specifically, in a case of an n-channel TFT, the pull-up/pull-down control means 132 carries out the following operations in a case of an n-channel TFT: (a) control the pull-up means 134 connected to a Vdd to which a high voltage of a clock is supplied, so as to supply a voltage (ON signal) that causes driving elements such as TFT elements in the display region A10 serving as an active area to be turned ON; or alternatively, (b) control the pull-down means 136 connected to a Vss to which a low voltage of a clock or a low voltage of a direct current is supplied, so as to supply a voltage (OFF signal) that causes driving elements such as TFT elements in the display region A10 serving as an active area to be turned off.

Although it has not been described in connection with the exemplary driving circuit illustrated in FIG. 4, in view of improving a potential supply capability to the gate bus-line, the driving circuit may be configured to include a so-called bootstrap capacitor. The bootstrap capacitor makes use of a change in a source potential or a drain potential of the pull-up means to raise a gate potential of the pull-up means.

In FIG. 1, there is no particular limitation in what elements are provided in the driving circuit B 60b that is arranged between the clock wiring 72 and the low-potential power supply line 70. For example, a three-terminal element, a resistance element, a capacitor element, etc may be provided as the element.

Among these elements, it is more effective in terms of narrowing the width of the frame that a large-sized circuit be provided in the driving circuit B 60b.

Specifically, for example, it is effective to provide the pull-up means 134 and the pull-down means 136 in the driving circuit B 60b.

Furthermore, in a case where the above-described bootstrap capacitor is provided, it is also effective to provide a circuit element (bootstrap capacitor element) in relation to forming of the bootstrap capacitor, in the driving circuit B 60b.

The above means and the like are large in size and have few contact holes. Therefore, arranging the means in the driving circuit B 60b causes few problems. That is, in the case where the driving circuit B 60b is covered with the seal 90, the seal 90 makes it easy to maintain the distance (gap) between the two opposing substrates at a preferred value. This is because the thickness of the seal 90 is not likely to vary due to the seal 90 entering into the contact holes.

(Integral Disposition of Driving Circuit)

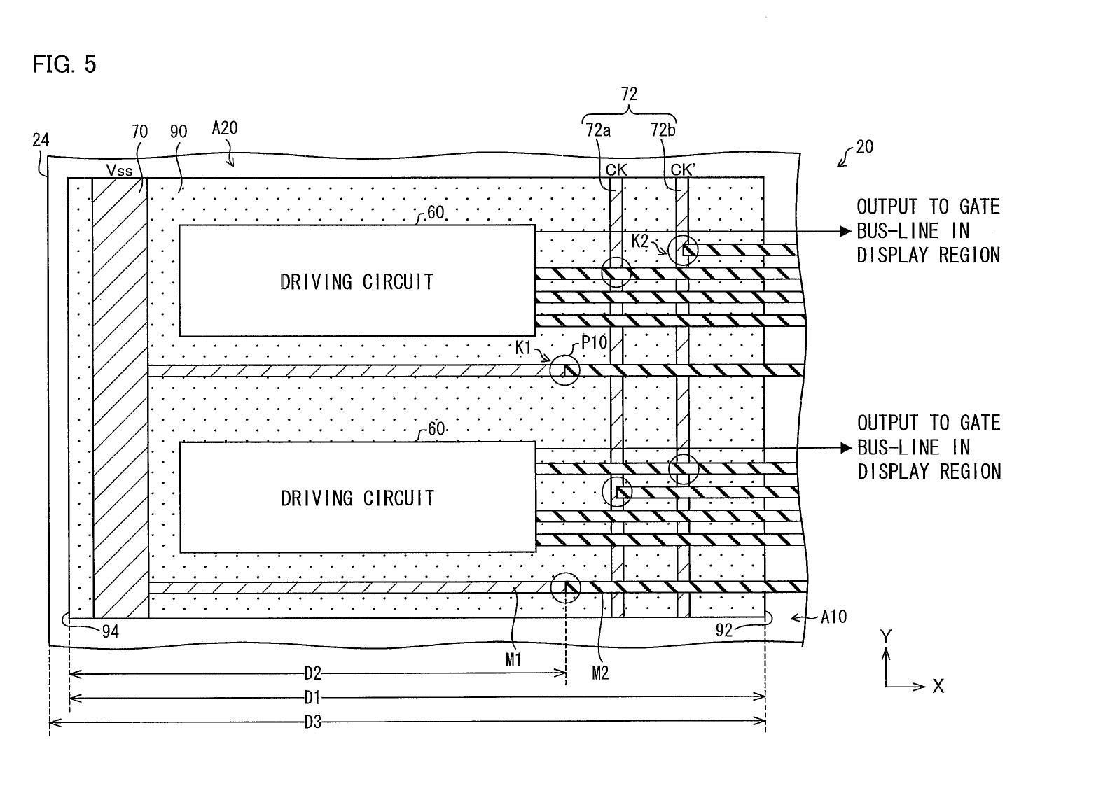

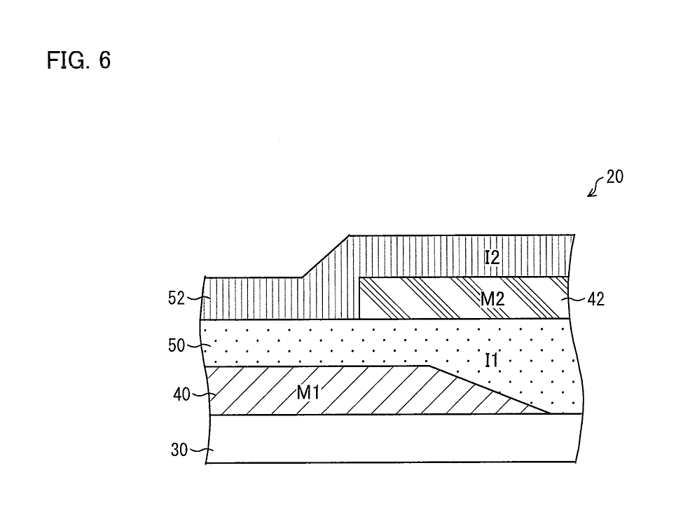

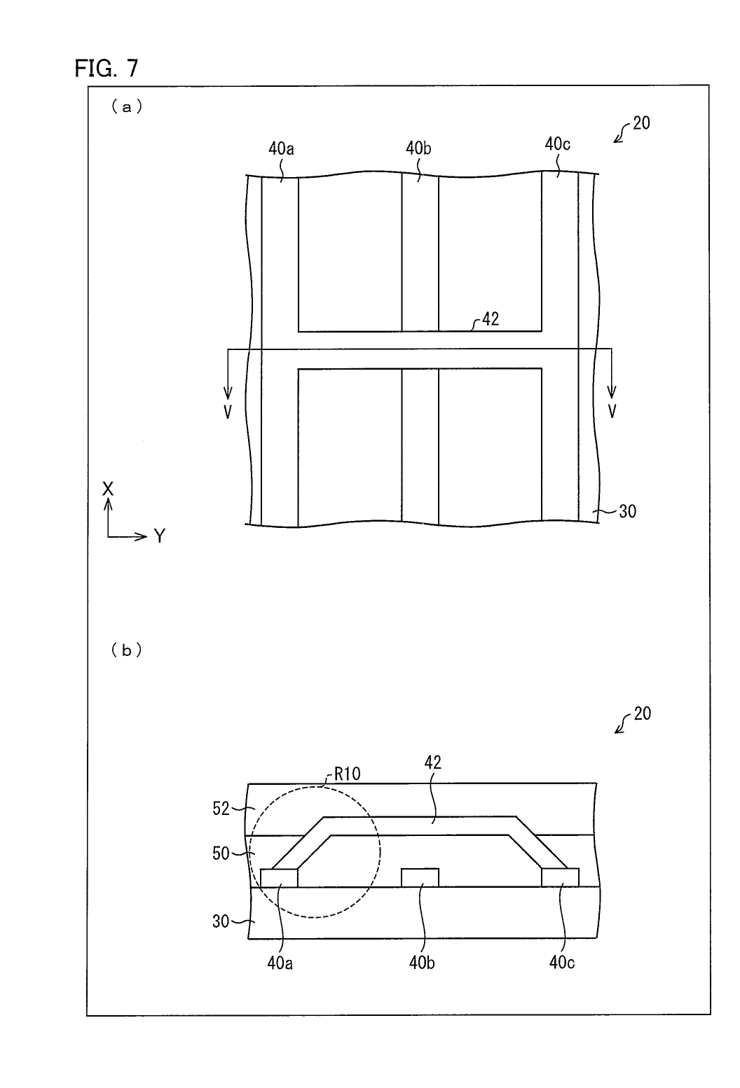

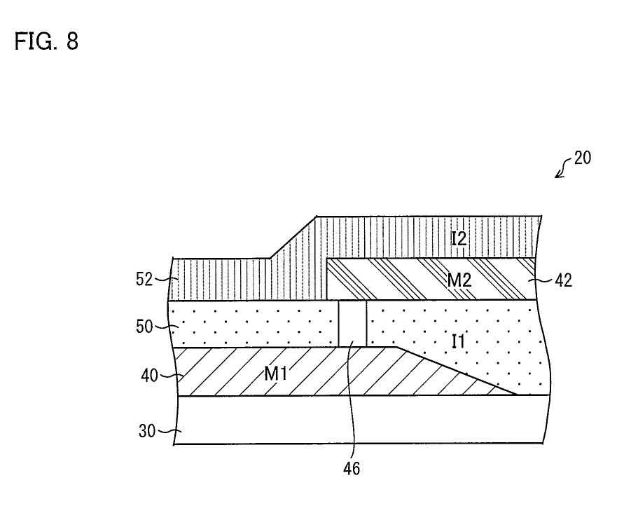

The foregoing description describes a configuration in which the driving circuit 60 is divided into a driving circuit A 60a and a driving circuit B 60b. However, the driving circuit 60 is not necessarily divided. The driving circuit 60 can also be configured as illustrated in FIG. 5. FIG. 5 shows an embodiment of the present invention and schematically illustrates a configuration of the TFT array substrate 20.

In the configuration illustrated in FIG. 5, the driving circuit 60 is not divided but is provided as one driving circuit between the low-potential power supply line 70 and the clock wires 72, which are types of signal lines that are provided in the peripheral region A20.

As illustrated in FIG. 5, such a configuration also allows the width D3 of the frame to be narrowed. In addition, it is also possible to prevent corrosion of metal by covering the connecting points P10 with the seal 90.

(Capacity in Intersecting Region)

As already described, the TFT array substrate according to the present embodiment has a region in which the wires that extend in the Y-direction intersect with the wires that extend in the X-direction.

In such an intersecting region, cross capacitance produced between the wires can cause a problem.

The TFT array substrate of the present invention allows narrowing the substantial width of the wires in this region by, e.g., hollowing a part of the wires.

Moreover, it is possible to reduce an area where the wires overlap each other, by narrowing the substantial width of the wires.

The invention being thus described, it will be obvious that the same way may be varied in many ways. Such variations are not to be regarded as a departure from the spirit and scope of the invention, and all such modifications as would be obvious to one skilled in the art are intended to be included within the scope of the following claims.

### INDUSTRIAL APPLICABILITY

The present invention is capable of narrowing a frame of a TFT array substrate and preventing corrosion of metal in the TFT array substrate. The present invention is thus suitably applicable to sensors, display devices such as liquid crystal devices, and the like.

1. A TFT array substrate comprising:
an insulating substrate on which TFT elements are arranged in a matrix manner;
a first metal and a second metal for providing on the insulating substrate gate bus-lines and source bus-lines, respectively, which gate bus-lines and source bus-lines are connected to the TFT elements;
an insulating layer provided between the first metal and the second metal so that the first metal and the second metal are provided as different layers on the insulating substrate;
at least one connecting point provided in a peripheral region around a TFT element region of the insulating substrate, for electrically connecting the first metal and the second metal together, the TFT element region being a region in which the TFT elements are arranged in the matrix manner;
a third metal that differs from the first metal and the second metal, via which the first metal and the second metal are electrically connected at the at least one connecting point; and
a driving circuit provided in the peripheral region for driving the TFT elements,
at least a part of the third metal being exposed at the at least one connecting point, and
at least a part of the driving circuit being provided in the peripheral region, between the at least one connecting point and an edge of the insulating substrate.

2. The TFT array substrate according to claim 1, wherein:
the exposed third metal is in no contact with air by use of an insulating material.

3. The TFT array substrate according to claim 1, wherein:
a plurality of the at least one connecting point are provided in the peripheral region, and
the exposed third metal in at least a part of the plurality of the at least one connecting point is in no contact with air by the third metal covered with an insulating material.

4. The TFT array substrate according to claim 1, wherein:
the exposed third metal in all of the at least one connecting point is in no contact with air by the third metal being covered with an insulating material.

5. The TFT array substrate according to claim 1, wherein:
an insulating material is provided in the peripheral region,
the insulating material being provided closer to the edge of the insulating substrate than the exposed third metal in all of the at least one connecting point, so that the exposed third metal is in no contact with air.

6. The TFT array substrate according to claim 5, wherein:
the exposed third metal in all of the at least one connecting point is surrounded by the insulating material provided along the edge of the insulating substrate.

7. The TFT array substrate according to claim 1, wherein:
an insulating material is provided in the peripheral region,
the insulating material covering the driving circuit provided between the at least one connecting point and an edge of the insulating substrate in the peripheral region.

8. The TFT array substrate according to claim 1, wherein:
at least one of a three-terminal element, a resistance element, and a capacitor element is provided in the driving circuit provided between the at least one connecting point and an edge of the insulating substrate in the peripheral region.

9. The TFT array substrate according to claim 1, wherein:
a three-terminal element, a resistance element, and a capacitor element are provided in the driving circuit provided between the at least one connecting point and an edge of the insulating substrate in the peripheral region.

10. The TFT array substrate according to claim 1, wherein:
at least one signal line is formed in the peripheral region, the signal line extending in a same direction as an edge of the insulating substrate in the peripheral region, and
at least a part of the driving circuit is provided between the at least one signal line and the edge of the insulating substrate.

11. The TFT array substrate according to claim 10, wherein:
the at least one signal line includes (i) a clock wire and (ii) a direct current power supply line for supplying a potential that causes the TFT elements to be turned off, and
the direct current power supply line is formed in the peripheral region between the driving circuit and the edge of the insulating substrate.

12. The TFT array substrate according to claim 1, wherein:
a wire formed by use of the first metal and a wire formed by use of the second metal are formed in the peripheral region in such a manner that the wire formed by use of the first metal and the wire formed by use of the second metal sandwich the insulating layer and intersect with each other in a planar view,
a substantial width of at least one of the wire formed by use of the first metal and the wire formed by use of the second metal being narrowed in a region in which the wire formed by use of the first metal and the wire formed by use of the second metal intersect with each other.

13. The TFT array substrate according to claim 1, wherein:
a wire formed by use of the first metal and a wire formed by use of the second metal are provided in the peripheral region in such a manner that the wire formed by use of the first metal and the wire formed by use of the second metal sandwich the insulating layer and intersect with each other in a planar view,
a part of at least one of the wire formed by use of the first metal and the wire formed by use of the second metal is hollowed in the region where the wire formed by use of the first metal and the wire formed by use of the second metal intersect with each other.

14. The TFT array substrate according to claim 2, wherein:
the insulating substrate is bonded to a counter substrate by use of a seal,
the insulating material serving as the seal.

15. The TFT array substrate according to claim 1, wherein:
pixel electrodes connected to the TFT elements are provided in the TFT element region,
the pixel electrodes being formed by use of the third metal.

16. The TFT array substrate according to claim 1, wherein:
the driving circuit provided in the peripheral region between the at least one connecting point and an edge of the insulating substrate includes a three-terminal element,
the three-terminal element being an element outputting a signal to the TFT elements.

17. The TFT array substrate according to claim 16, wherein:
the three-terminal element makes up a pull-up circuit for outputting to the TFT elements a signal that causes the TFT elements to be turned on.

18. The TFT array substrate according to claim 16, wherein:
the three-terminal element makes up a pull-down circuit for outputting to the TFT elements a signal that causes the TFT elements to be turned off.

19. The TFT array substrate according to claim 16, wherein:
the driving circuit provided in the peripheral region between the at least one connecting point and an edge of the insulating substrate includes a bootstrap capacitor element.

20. A liquid crystal display device comprising a TFT array substrate as set forth in claim 1.
